(19) United States
(12) Patent Application Publication
(10) Pub. No.: US 2017/0294544 A1
(43) Pub. Date: Oct. 12, 2017

(54) THIN FILM TRANSISTOR AND METHOD THEREOF, ARRAY SUBSTRATE, AND DISPLAY APPARATUS

(71) Applicant: BOE TECHNOLOGY GROUP CO., LTD., Beijing (CN)

(72) Inventor: Lungpao HSIN, Beijing (CN)

(21) Appl. No.: 15/324,607

(22) PCT Filed: Jun. 7, 2016
(86) PCT No.: PCT/CN2016/085100

§ 371 Date: Jan. 6, 2017

(30) Foreign Application Priority Data
Nov. 5, 2015 (CN) 201510749700.5

(51) Int. Cl. H01L 29/786; H01L 27/12; H01L 29/49; H01L 29/66

(52) U.S. Cl. CPC H01L 29/78618; H01L 29/6675; H01L 27/1248; H01L 27/1259; H01L 29/4908

(57) ABSTRACT

In various embodiments of the disclosed subject matter, a method for forming a thin film transistor (TFT), a related TFT, array substrate, and display apparatus are provided. The method comprises: forming a pattern of an active layer on a base substrate and insulated from a gate electrode; forming a first initial ohmic contacting layer and a second initial ohmic contacting layer on the active layer; forming a source electrode on the first initial ohmic contacting layer, and a drain electrode on the second initial ohmic contacting layer; and performing a heating treatment to the base substrate having the source electrode and the drain electrode thereon, such that metal atoms in the source electrode diffuse to the first initial ohmic contacting layer to form a first ohmic contacting layer, and metal atoms in the drain electrode diffuse to the second initial ohmic contacting layer to form a second ohmic contacting layer.

### CROSS-REFERENCES TO RELATED APPLICATIONS

This PCT patent application claims priority of Chinese Patent Application No. 201510749700.5 filed on Nov. 5, 2015, the entire content of which is incorporated by reference herein.

### TECHNICAL FIELD

The disclosed subject matter generally relates to semiconductor technologies and, more particularly, relates to a thin film transistor, a method for forming the thin film transistor, a related array substrate, and a related display apparatus.

### BACKGROUND

In a pixel unit of various display devices, thin film transistors (TFTs) that are driven by applying driving voltages are widely used. In some existing TFTs, the active layer is made by amorphous silicon (a-Si) material that has a good stability and a good processability. But the a-Si material has a low carrier mobility that do not meet the requirements of large-size and high-resolution display. Especially the a-Si material cannot reach the requirements of the next generation of active matrix organic light emitting display device (AMOLED).

Compared with a-Si TFTs, TFTs, especially low-temperature polysilicon TFTs, have a higher electron mobility, better liquid crystal properties, and less leakage current. So polysilicon TFTs are gradually replacing the a-Si TFTs, and are becoming a mainstream in the field.

However, for the existing polysilicon TFTs, an aspect ratio of the thin film transistor channel defined by a gate electrode self-alignment process has a relative large width to length ratio. Additionally, the source electrode and the drain electrode have a relative poor ohmic contacting performance to the active layer.

Accordingly, it is desirable to provide a thin film transistor, a method for forming the thin film transistor, a related array substrate, and a related display apparatus to at least partially alleviate one or more problems set forth above and to solve other problems in the art.

### BRIEF SUMMARY

In accordance with some embodiments of the disclosed subject matter, a thin film transistor, a method for forming the thin film transistor, a related array substrate, and a related display apparatus are provided.

An aspect of the disclosed subject matter provides a method for forming a thin film transistor, comprising: forming a pattern of an active layer, on a base substrate and insulated from a gate electrode; forming a pattern of a first initial ohmic contacting layer and a second initial ohmic contacting layer on the active layer; forming a pattern of a source electrode on the first initial ohmic contacting layer, and a pattern of a drain electrode on the second initial ohmic contacting layer; and performing a heating treatment to the base substrate having the source electrode and the drain electrode thereon, such that metal atoms in the source electrode diffuse to the first initial ohmic contacting layer to form a first ohmic contacting layer, and metal atoms in the drain electrode diffuse to the second initial ohmic contacting layer to form a second ohmic contacting layer.

In some embodiments, the first initial ohmic contacting layer and the second initial ohmic contacting layer are located in a same layer and are oppositely positioned; and a material of the first initial ohmic contacting layer and the second initial ohmic contacting layer is metal oxide or metal oxynitride.

In some embodiments, the method further comprises: after forming the pattern of the first initial ohmic contacting layer and the second initial ohmic contacting layer, forming a pattern of the gate electrode; wherein the gate electrode is insulated from the first initial ohmic contacting layer and the second initial ohmic contacting layer.

In some embodiments, the pattern of the gate electrode is formed before forming the pattern of the source electrode and the drain electrode.

In some embodiments, the method further comprises: after forming the pattern of the first initial ohmic contacting layer and the second initial ohmic contacting layer and before forming the pattern of the gate electrode, forming a gate insulating layer on the first initial ohmic contacting layer and the second initial ohmic contacting layer.

In some embodiments, the method further comprises: after forming the pattern of the gate electrode and before forming the pattern of the source electrode and the drain electrode, forming an interlayer dielectric layer covering the gate electrode; and forming a first via-hole and a second via-hole passing through the gate insulating layer and the interlayer dielectric layer, wherein the first via-hole is used for electrically connecting the first initial ohmic contacting layer with a to-be-formed source electrode, and the second via-hole is used for electrically connecting the second initial ohmic contacting layer with a to-be-formed drain electrode.

In some embodiments, the metal oxide includes at least one element of Indium (In), zinc (Zn), gallium (Ga), and tin (Sn).

In some embodiments, the metal oxynitride includes at least one element of Indium (In), zinc (Zn), gallium (Ga), and tin (Sn).

Another aspect of the disclosed subject matter provides a thin film transistor, comprising: a gate electrode; an active layer insulated from the gate electrode; a source electrode and a drain electrode on the active layer; a first ohmic contacting layer located between the source electrode and the active layer, wherein a material of the first ohmic contacting layer is formed by diffusing metal atoms in the source electrode to a metal oxide or a metal oxynitride; and a second ohmic contacting layer located between the drain electrode and the active layer, wherein a material of the second ohmic contacting layer is formed by diffusing metal atoms in the drain electrode to a metal oxide or a metal oxynitride; wherein the source electrode is electrically connected with the active layer through the first ohmic contacting layer, and the drain electrode is electrically connected with the active layer through the second ohmic contacting layer.

In some embodiments, a material of the active layer is polysilicon.

In some embodiments, the gate electrode is located above the first ohmic contacting layer and the second ohmic contacting layer.

In some embodiments, the source electrode and the drain electrode are located above the gate electrode.

In some embodiments, the thin film transistor further comprises a gate insulating layer between the gate electrode and the first ohmic contacting layer and between the gate electrode and the second ohmic contacting layer.

In some embodiments, the thin film transistor further comprises: an interlayer dielectric layer between the gate electrode and the source electrode as well as the drain electrode; and a first via-hole and a second via-hole passing through the gate insulating layer and the interlayer dielectric layer; wherein the first initial ohmic contacting layer is electrically connected to source electrode through the first via-hole, and the second initial ohmic contacting layer is electrically connected with the drain electrode through the second via-hole.

In some embodiments, the metal oxide includes at least one element of Indium (In), zinc (Zn), gallium (Ga), and tin (Sn).

In some embodiments, the metal oxynitride includes at least one element of Indium (In), zinc (Zn), gallium (Ga), and tin (Sn).

In some embodiments, the metal atoms are copper atoms.

Another aspect of the disclosed subject matter provides an array substrate, comprising the disclosed thin film transistor.

In some embodiments, the array substrate further comprises: a planarization layer and a pixel electrode that are located above the thin film transistor; wherein the pixel electrode is electrically connected with the drain electrode of the thin film transistor.

In some embodiments, the array substrate is used in an liquid crystal display panel; and the pixel electrode is a pixel electrode of the liquid crystal display panel.

In some embodiments, the array substrate is used in an organic electroluminescent display panel; and the pixel electrode is an anode layer or a cathode layer of an organic light emitting structure of the organic electroluminescent display panel.

Another aspect of the disclosed subject matter provides a display apparatus, comprising the disclosed array substrate.

Other aspects of the disclosed subject matter can be understood by those skilled in the art in light of the description, the claims, and the drawings of the present disclosure.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements. It should be noted that the following drawings are merely examples for illustrative purposes according to various disclosed embodiments and are not intended to limit the scope of the present disclosure.

FIG. 1 is a schematic structural diagram of an existing polysilicon TFT;

FIG. 2 is a flowchart of an exemplary method for fabricating a TFT in accordance with some embodiments of the disclosed subject matter;

FIG. 3 is a schematic structural diagram of a width and a length of an exemplary TFT channel in accordance with some embodiments of the disclosed subject matter;

FIGS. 4a-4i are schematic structural diagrams of an exemplary TFT at certain stages of a fabricating process in accordance with some embodiments of the disclosed subject matter;

FIG. 5 is a schematic structural diagram of an exemplary TFT in accordance with some embodiments of the disclosed subject matter; and

FIG. 6 is a schematic structural diagram of an exemplary array substrate in accordance with some embodiments of the disclosed subject matter.

### DETAILED DESCRIPTION

For those skilled in the art to better understand the technical solution of the disclosed subject matter, reference will now be made in detail to exemplary embodiments of the disclosed subject matter, which are illustrated in the accompanying drawings. Wherever possible, the same reference numbers will be used throughout the drawings to refer to the same or like parts.

In accordance with various embodiments, the disclosed subject matter provides a thin film transistor, a method for forming the thin film transistor, a related array substrate, and a related display apparatus.

It should be noted that, the thickness and shape of each layer in the drawings do not reflect the actual ratios of the thin film transistor. The purpose of the drawings are only for illustrating the content of the disclosed subject matter.

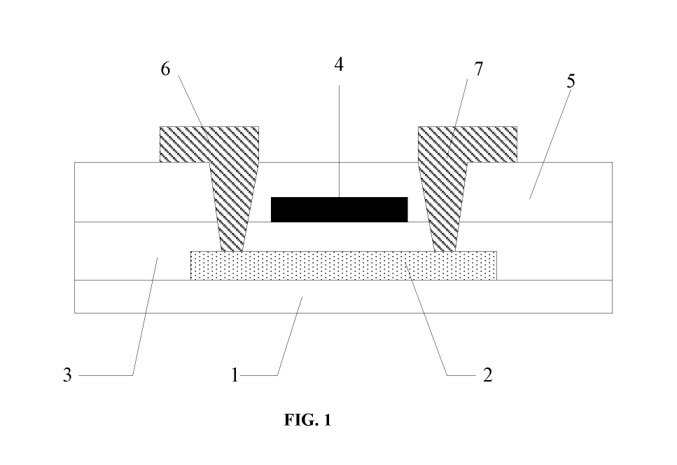

Referring to FIG. 1, a schematic structural diagram of an existing polysilicon TFT is shown. As illustrated, a typical structure of a conventional polysilicon TFT includes a base substrate 1, an active layer 2 located on the base substrate 1, a gate insulating layer 3 located on the active layer 2, a gate electrode 4 located on the gate insulating layer 3, a dielectric layer 5 located on the gate electrode 4, and a source electrode 6 and a drain electrode 7 located on the dielectric layer 5. The source electrode 6 and the drain electrode 7 are electrically connected to the active layer 2 through via-holes that are respectively pass through the dielectric layer 5 and the gate insulating layer 3.

As mentioned in the background section, in the existing polysilicon TFT, an aspect ratio of the thin film transistor channel defined by a gate electrode self-alignment process has a relative large width to length ratio. Additionally, the source electrode and the drain electrode have a relative poor ohmic contacting performance to the active layer.

Therefore, how to improve the ohmic contacting performance of a polysilicon TFT, and how to reduce the width to length ratio of the polysilicon TFT channel are serious and urgent technical problems to those skilled in the polysilicon TFTs.

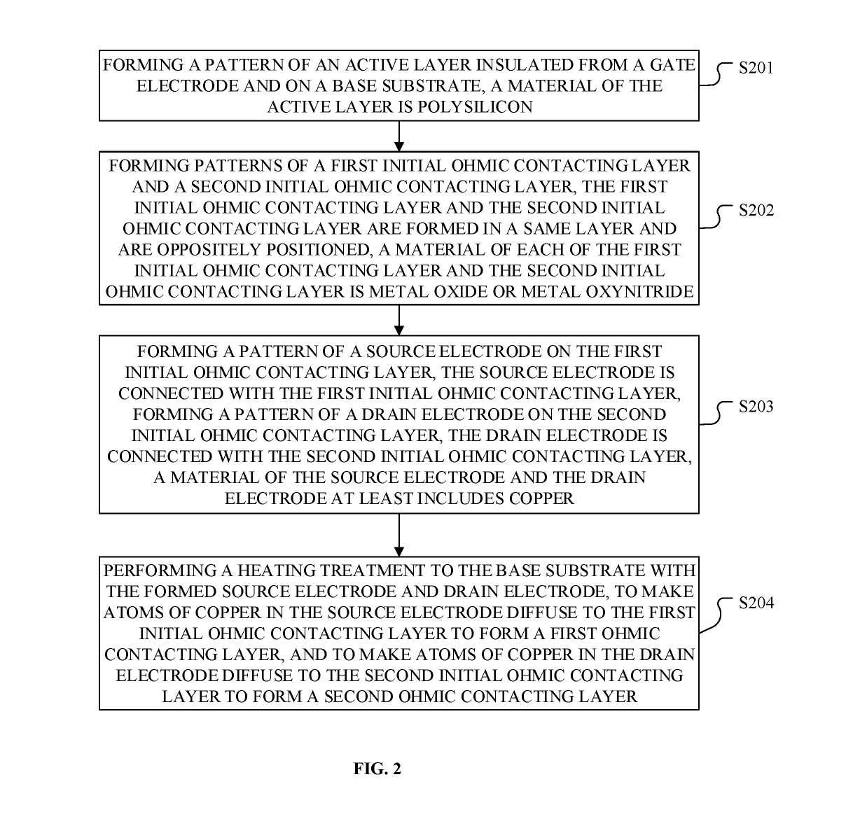

Referring to FIG. 2, a flowchart of an exemplary method for fabricating a TFT is shown in accordance with some embodiments of the disclosed subject matter. As illustrated, the method includes forming a pattern of an gate electrode on a base substrate. Specifically, the following steps are included.

Step S201: forming a pattern of an active layer insulated from a gate electrode and on a base substrate, a material of the active layer is polysilicon;

Step S202: forming patterns of a first initial ohmic contacting layer and a second initial ohmic contacting layer, the first initial ohmic contacting layer and the second initial ohmic contacting layer are formed in a same layer and are oppositely positioned, a material of each of the first initial ohmic contacting layer and the second initial ohmic contacting layer is metal oxide or metal oxynitride;

S203, forming a pattern of a source electrode on the first initial ohmic contacting layer, the source electrode is electrically connected with the first initial ohmic contacting layer, forming a pattern of a drain electrode on the second initial ohmic contacting layer, the drain electrode is electrically connected with the second initial ohmic contacting layer, a material of the source electrode and the drain electrode at least includes copper;

S204, performing a heating treatment to the base substrate with the formed source electrode and drain electrode, to make copper atoms in the source electrode diffuse to the first initial ohmic contacting layer to form a first ohmic contacting layer, and to make copper atoms in the drain electrode diffuse to the second initial ohmic contacting layer to form a second ohmic contacting layer.

In some embodiments of the disclosed method for fabricating the TFT, after forming the pattern of the active layer and before forming the pattern of the source electrode and the drain electrode, patterns of a first initial ohmic contacting layer and a pattern of a second initial ohmic contacting layer can be formed. The first initial ohmic contacting layer and the second initial ohmic contacting layer are oppositely positioned. A material of the first initial ohmic contacting layer and the second initial ohmic contacting layer includes oxide.

After forming the pattern of the source electrode and the drain electrode, a heating treatment can be performed to the base substrate with the formed source electrode and drain electrode. During the heating treatment process, copper atoms in the source electrode and the drain electrode may be diffused there-from. The atoms of copper in the source electrode can diffuse to the first initial ohmic contacting layer, to make the oxide material have a good conductivity, and form a first ohmic contacting layer. The atoms of copper in the drain electrode can diffuse to the second initial ohmic contacting layer, to make the oxide material have a good conductivity, and form a second ohmic contacting layer.

As disclosed herein, a first ohmic contacting layer and a second ohmic contacting layer are formed between the active layer and the source electrode/drain electrode respectively. Since the first ohmic contacting layer and the second ohmic contacting layer have a good conductivity, the source electrode and the drain electrode can have a good ohmic contacting performance with the active layer, thereby improving the performance of TFT.

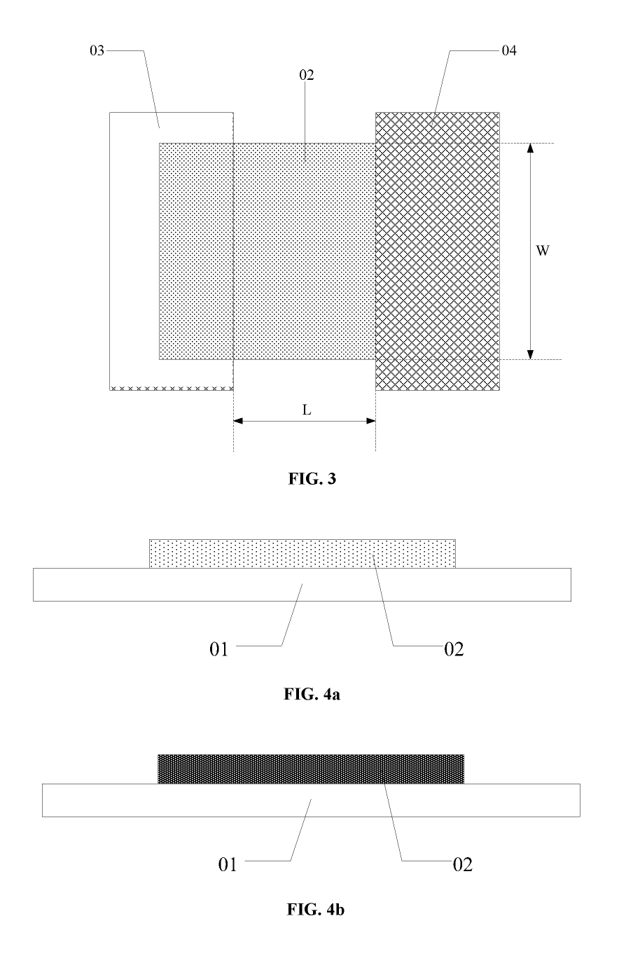

Additionally, referring to FIG. 3, a schematic structural diagram of a width and a length of an exemplary TFT channel is shown in accordance with some embodiments of the disclosed subject matter.

In the disclosed method for fabricating the TFT, a width W of the TFT channel can be controlled by the pattern of the active layer 02, a length L of TFT channel can be controlled by the pattern of the first initial ohmic contacting layer 03 and the second initial ohmic contacting layer 04.

The pattern of the first initial ohmic contacting layer 03 and the second initial ohmic contacting layer 04 can be formed by using a patterning process. Since the patterning process can accurately control the patterns of the first initial ohmic contacting layer 03, the second initial ohmic contacting layer 04, and the active layer 02, the length L and width W of the TFT channel can be accurately controlled. Therefore, the width to length ratio (W/L) of the TFT channel can be accurately controlled, and can also be controlled to be a small width to length ratio of TFT channel.

In some embodiments, the metal oxide or metal oxynitride includes at least one element of indium (In), zinc (Zn), gallium (Ga), tin (Sn), or any combinations thereof.

In some embodiments, the material of the source electrode and the drain electrode can be copper, a copper alloy, or any other suitable material containing copper.

Further, the heating treatment performed to the base substrate with source electrode and the drain electrode can be a rapid thermal annealing process, or any other suitable heating treatment process.

In some embodiments, the patterns of the first initial ohmic contacting layer and the second initial ohmic contacting layer can be formed in a one-time patterning process, or be formed by separate patterning processes.

It should be noted that, the pattern of the gate electrode can be formed before forming the pattern of the actively layer, or after forming the patterns of the first initial ohmic contacting layer and the second initial ohmic contacting layer.

Generally, a required temperature for forming the polysilicon material active layer is relatively high, and a high temperature may affect the layers below the active layer. Therefore, preferably, the pattern of the gate electrode can he formed after forming the patterns of the first initial ohmic contacting layer and the second initial ohmic contacting layer.

Additionally, the gate electrode is insulated to the first initial ohmic contacting layer and the second initial ohmic contacting layer to ensure that the active layer and the gate electrode are insulated to each other.

Further, after forming the patterns of the first initial ohmic contacting layer and the second initial ohmic contacting layer, the patterns of the gate electrode, the source electrode, and the drain electrode can be formed simultaneously in a one-time process. In some other embodiments, the pattern of the gate electrode can be formed before forming the patterns of the source electrode and the drain electrode, or after forming the patterns of the source electrode and the drain electrode.

In some embodiments, when the TFT is used for controlling a pixel unit of a display panel, the drain electrode of the TFT is electrically connected to a pixel electrode of the pixel unit, and the pixel electrode is generally located above the TFT. Therefore, the pattern of the gate electrode is formed before forming the patterns of the source electrode and the drain electrode. So that the source electrode and the drain electrode are located above the gate electrode to facilitate the electrical connection between the drain electrode and the pixel electrode.

Further, in order to insulating the gate electrode to both the first initial ohmic contacting layer and the second initial ohmic contacting layer, after forming the patterns of the first initial ohmic contacting layer and the second initial ohmic contacting layer, and before forming the pattern of the gate electrode, a gate insulating layer can be formed on the first initial ohmic contacting layer and the second initial ohmic contacting layer.

Further, in order to insulating the gate electrode to both the source electrode and the drain electrode, after forming the pattern of the gate electrode, and before forming the patterns of the source electrode and the drain electrode, an interlayer dielectric layer covering the gate electrode can he formed.

A first via-hole and a second via-hole passing through the gate insulating layer and the interlayer dielectric layer can be formed. The first via-hole is used for electrically connecting the first initial ohmic contacting layer with the to-be-formed source electrode. The second via-hole is used for electrically connecting the second initial ohmic contacting layer with the to-be-formed drain electrode.

Specifically, forming the active layer can include: forming an amorphous silicon thin film on the base substrate, using an excimer laser to irradiate the amorphous silicon thin film to transform the amorphous silicon thin film into a polycrystalline silicon thin film, patterning the polycrystalline silicon thin film to form a pattern of the active layer. Any other suitable process can be used to form the active layer.

The patterns of the source electrode and the drain electrode can be formed in a one-time patterning process, or can be formed separately.

Further, after forming the pattern of the actively layer, and before forming the first initial ohmic contacting layer and the second initial ohmic contacting layer, an ion implantation process can be performed to the active layer to improve the performance of the TFT.

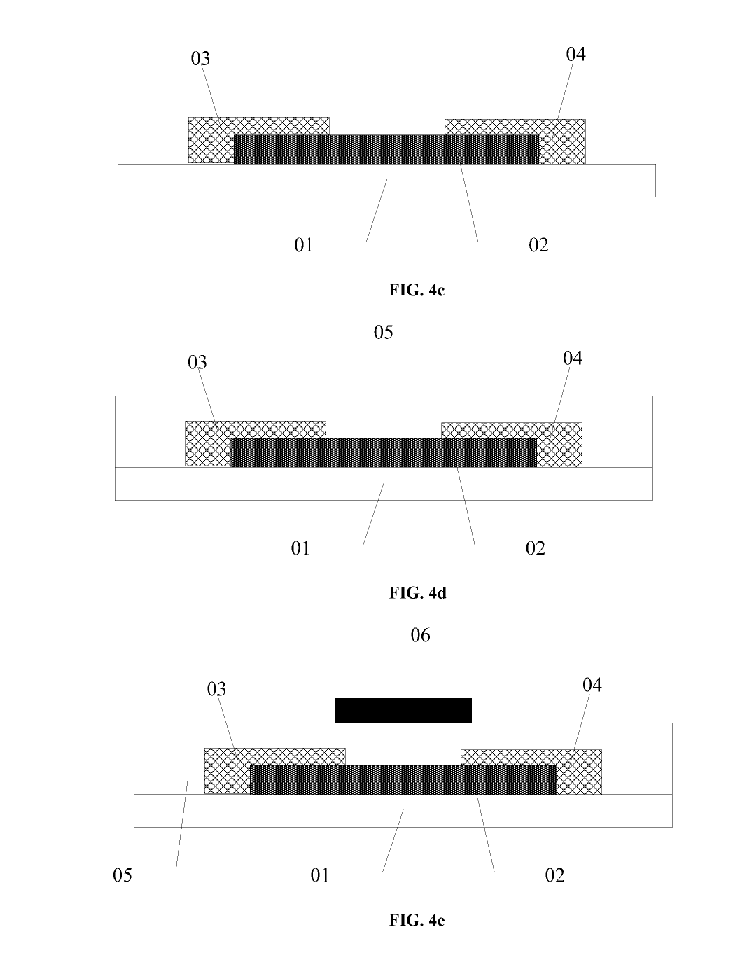

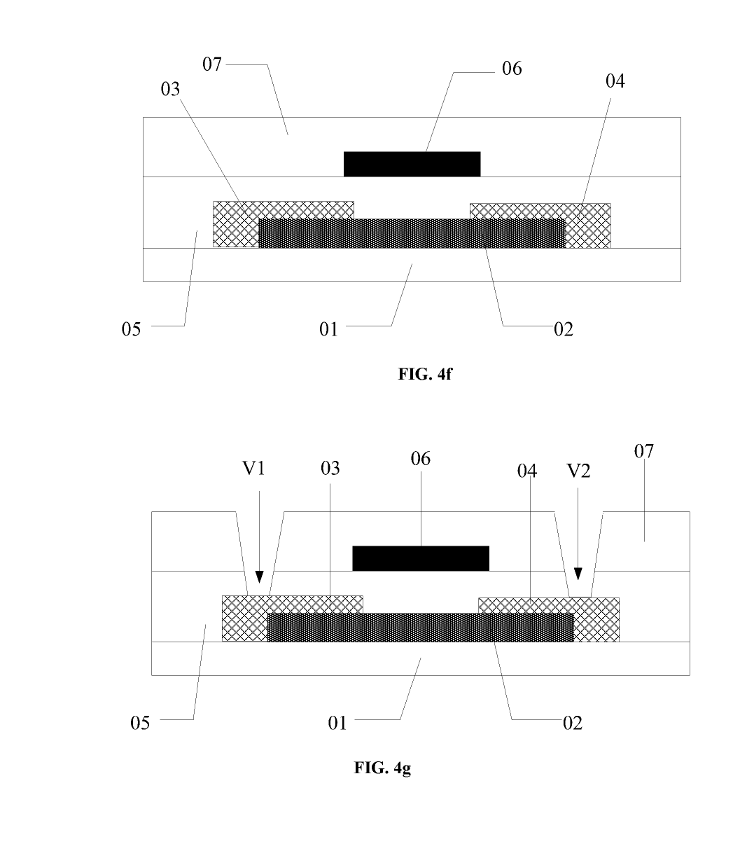

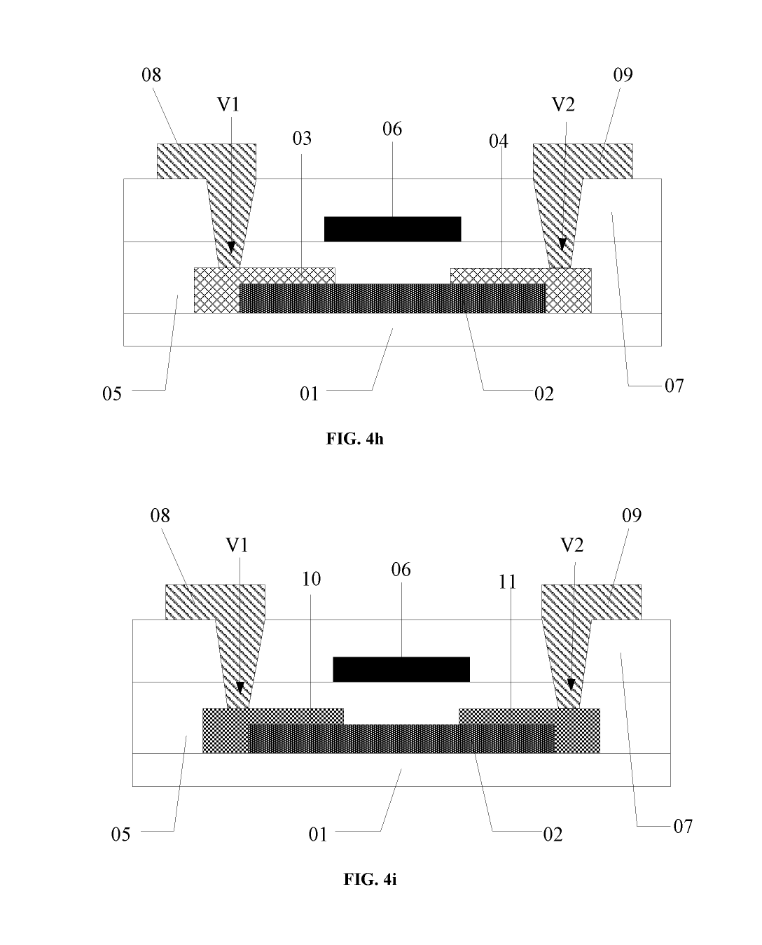

Next, a specific example is described in details for illustrating the method for fabricating the TFT. Referring to FIGS. 4a-4i, schematic structural diagrams of an exemplary TFT on different stages of the fabricating process are shown in accordance with some embodiments of the disclosed subject matter.

Stage (1): forming a pattern of the active layer 02 on the base substrate 01, as illustrated in FIG. 4a.

The material of the active layer is polysilicon.

Stage (2): performing an ion implantation process to the active layer 02, as illustrated in FIG. 4b.

Stage (3): using a one-time patterning process to form the patterns of the first initial ohmic contacting layer 03 and the second initial ohmic contacting layer 04 on the active layer 02, as illustrated in FIG. 4c.

The first initial ohmic contacting layer 03 and the second initial ohmic contacting layer 04 are located in a same layer, and are oppositely positioned.

A material of the first initial ohmic contacting layer and the second initial ohmic contacting layer is metal oxide or metal oxynitride.

In some embodiments, the metal oxide or metal oxynitride includes at least one element of indium (In), zinc (Zn), gallium (Ga), and tin (Sn).

Stage (4): forming a gate insulating layer 05 covering the first initial ohmic contacting layer 03, the second initial ohmic contacting layer 04, and the active layer 02, as illustrated in FIG. 4d;

Stage (5): forming a pattern of gate electrode 06 on the gate insulating layer 05, as illustrated in FIG. 4e;

In some embodiments, a material of the gate electrode 06 is copper.

Stage (6): forming an interlayer dielectric layer 07 covering the gate electrode 06, as shown in FIG. 4f.

Stage (7): forming a first contacting hole V1 and a second contacting hole V2 that pass through the gate insulating layer 05 and the interlayer dielectric layer 07, as shown in FIG. 4G.

Stage (8): forming a pattern of a source electrode 08 and a drain electrode 09, and the source electrode 08 is electrically connected to the first initial ohmic contacting layer 03 through the first contacting hole V1, and the drain electrode 09 is electrically connected to the second ohmic contacting layer 04 through the second contacting hole V2, as shown in FIG. 4h.

A material of the source electrode 08 and drain electrode 09 can be copper, copper alloy, or any other material comprising copper.

Stage (9): performing a heating treatment to the base substrate 01 to make copper atoms in the source electrode 08 diffuse to the first initial ohmic contacting layer 03 to form a first ohmic contacting layer 10, and make copper atoms in the drain electrode 09 diffuse to the second initial ohmic contacting layer 04 to form a second ohmic contacting layer 11, as illustrated in FIG. 4i.

The TFT can be fabricated through the Stages from (1) to (9). It should he noted that, the Stages (1), (3), (5), (7) and (8) include performing patterning processes. The patterning process may only include a lithography process, or may include a photolithography process and an etching process, or may also include printing, ink printing, or any other suitable process for forming a predetermined pattern. The photolithography process can include film formation, exposure, development, and any other suitable process, and can use photoresist, mask, exposure machine, etc. In some embodiments, appropriate patterning process can be selected according to the structures to be formed.

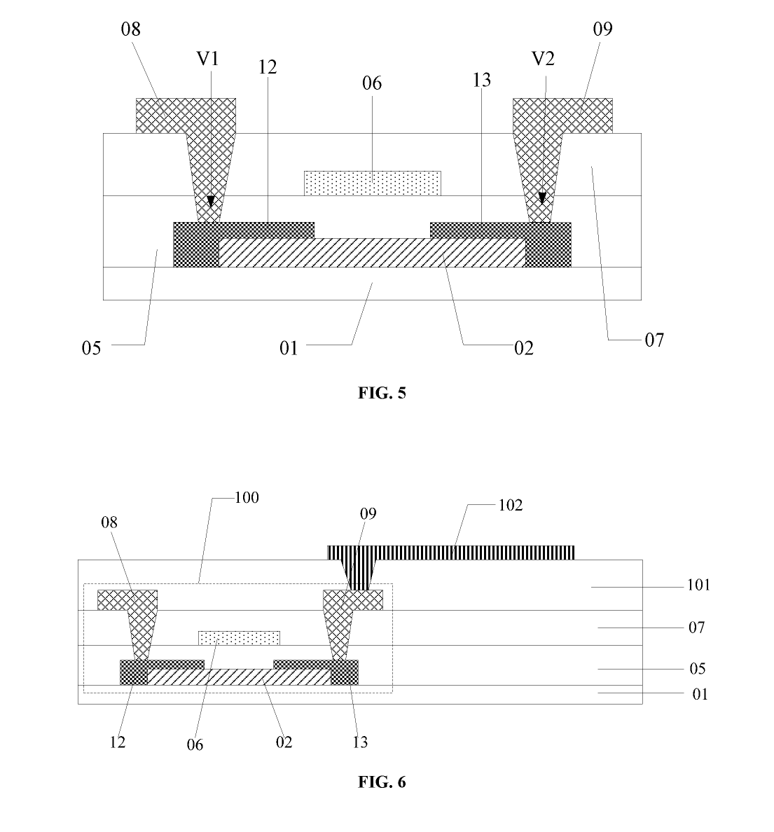

Another aspect of the disclosed subject matter provides a TFT. As illustrated in FIG. 5, a schematic structural diagram of an exemplary TFT is shown in accordance with some other embodiments of the disclosed subject matter.

The TFT can include a base substrate 01, a gate electrode 06 on the base substrate 01, an active layer 02 that is insulated from the gate electrode 06, a source electrode 08 and a drain electrode 09 on the active layer 02 and electrically connected with the active layer 01 A material of the active layer 02 is polysilicon.

The TFT can further include a first ohmic contacting layer 12 located between the source electrode 08 and the active layer 02, and a second ohmic contacting layer 13 located between the drain electrode 09 and the active layer 02. The source electrode 08 is electrically connected with the active layer 02 through the first ohmic contacting layer 12, and the drain electrode 09 is electrically connected with the active layer 02 through the second ohmic contacting layer 13.

A material of the source electrode 08 and the drain electrode 09 at least includes copper. A material of the first ohmic contacting layer 12 and the second ohmic contacting layer 13 is formed by diffusing the copper atoms from the source electrode 08 and drain electrode 09 respectively to a metal oxide or a metal oxynitride.

The disclosed TFT includes a source electrode and a drain electrode with the copper material, and a first ohmic contacting layer and a second ohmic contacting layer formed between the active layer and the source electrode/drain electrode respectively. The material of the first ohmic contacting layer and the second ohmic contacting layer is formed by diffusing the copper atoms from the source electrode and drain electrode respectively to a metal oxide or a metal oxynitride. Since the metal oxide or the metal oxynitride doped with copper atoms can have a good conductivity, the first ohmic contacting layer and the second ohmic contacting layer have a good conductivity. So the source electrode and the drain electrode can have a good ohmic contacting performance with the active layer, thereby the performance of TFT is improved.

It should be noted that, the disclosed TFT can have a top gate structure, a bottom gate structure, or a dual gate structure.

In some embodiments, the material of the active layer is polysilicon which needs a high temperature to be formed, and the high temperature may affect the layers below the active layer, so that the TFT has a top gate structure. That is, the gate electrode is located above the active layer. Therefore, as illustrated in FIG. 5, the gate electrode 06 is located above the first ohmic contacting layer 12 and the second ohmic contacting layer 13.

Further, when the TFT has a top gate structure, the source electrode and the drain electrode can be located either above the gate electrode, or below the gate electrode, as long as the gate electrode is insulated from the source electrode and the drain electrode.

In some embodiments, when the disclosed. TFT is applied for display panel, the drain electrode of the TFT is usually electrically connected with the pixel electrode located above the drain electrode. Therefore, as illustrated in FIG. 5, the source electrode 08 and the drain electrode 09 are both located above the gate electrode 06.

The disclosed TFT as illustrated in FIG. 5 can further include a gate insulating layer 05 between the gate electrode 06 and the first ohmic contacting layer 12 as well as the second ohmic contacting layer 13.

The disclosed TFT as illustrated in FIG. 5 can further include an interlayer dielectric layer 07 between the gate electrode 06 and the source electrode 08 as well as the drain electrode 09.

The source electrode 08 is electrically connected with the first ohmic contacting layer 12 by the first contacting hole V1 that passes through the gate insulating layer 05 and the interlayer dielectric layer 07. The drain electrode 09 is electrically connected with the second ohmic contacting layer 13 by the second contacting hole V2 that passes through the gate insulating layer 05 and the interlayer dielectric layer 07.

Additionally, the above mentioned metal oxide or metal oxynitride includes at least one element of indium (In), zinc (Zn), gallium (Ga), and tin (Sn).

A material of the source electrode and drain electrode can be copper, copper alloy, or any other suitable material that includes copper.

Further, a material of the gate electrode is copper, because the copper has a relatively small conductivity which may further improve the performance of the TFT.

Another aspect of the disclosed subject matter provides an array substrate. As illustrated in FIG. 6, a schematic structural diagram of an exemplary array substrate is shown in accordance with some other embodiments of the disclosed subject matter.

In some embodiments, the array substrate includes a disclosed TFT described above in connection with FIG. 5. Further, the array substrate includes a planarization layer 101 and a pixel electrode 102 that are located on the TFT, as illustrated in FIG. 6.

The pixel electrode 102 can be electrically connected with the drain electrode 09 of the TFT through a via hole.

Specifically, the disclosed array substrate can be applied to an liquid crystal display (LCD) panel, or an organic electroluminescent display (OLED) panel.

When the array substrate is applied to an LCD panel, the pixel electrode is referred to an pixel electrode of the LCD panel. When the array substrate is applied to an OLED panel, the pixel electrode is referred to an anode layer or a cathode layer of an organic light emitting pixel electrode structure.

Another aspect of the disclosed subject matter provides a display apparatus, including a disclosed array substrate described above in connection with FIG. 6.

The display apparatus can be a smart phone, a tablet computer, a television, a monitor, a notebook computer, a digital picture frame, a navigation system, or any other suitable product or component that has a display function.

Accordingly, a thin film transistor, a method for forming the thin film transistor, a related array substrate, and a related display apparatus are provided. In some embodiments of the disclosed method for fabricating the TFT, after forming the pattern of the active layer and before forming the pattern of the source electrode and the drain electrode, patterns of a first initial ohmic contacting layer and a pattern of a second initial ohmic contacting layer can be formed. The first initial ohmic contacting layer and the second initial ohmic contacting layer are oppositely positioned. A material of the first initial ohmic contacting layer and the second initial ohmic contacting layer is oxide. After forming the pattern of the source electrode and the drain electrode, a heating treatment can be performed to the base substrate with the formed source electrode and drain electrode. During the heating treatment process, copper atoms in the source electrode and the drain electrode may be diffused there-from. The atoms of copper in the source electrode can diffuse to the first initial ohmic contacting layer, to make the oxide material have a good conductivity, and form a first ohmic contacting layer. The atoms of copper in the drain electrode can diffuse to the second initial ohmic contacting layer, to make the oxide material have a good conductivity, and form a second ohmic contacting layer. Compared to the prior arts, a first ohmic contacting layer and a second ohmic contacting layer are formed between the active layer and the source electrode drain electrode respectively. Since the first ohmic contacting layer and the second ohmic contacting layer have a good conductivity, the source electrode and the drain electrode can have a good ohmic contacting performance with the active layer, thereby improving the performance of TFT. Further, in the disclosed method for fabricating the TFT, a width of the TFT channel can be controlled by the pattern of the active layer, a length of TFT channel can be controlled by the pattern of the first initial ohmic contacting layer and the second initial ohmic contacting layer. And the pattern of the first initial ohmic contacting layer 03 and the second initial ohmic contacting layer 04 can be formed by using a patterning process. Since the patterning process can accurately control the patterns of the first initial ohmic contacting layer, the second initial ohmic contacting layer, and the active layer, the length and width of the TFT channel can be accurately controlled. Therefore, the width to length ratio of the TFT channel can be accurately controlled, and can also be controlled to be a small width to length ratio of TFT channel.

The provision of the examples described herein (as well as clauses phrased as “such as,” “e.g.,” “including,” and the like) should not be interpreted as limiting the claimed subject matter to the specific examples; rather, the examples are intended to illustrate only some of many possible aspects.

Although the disclosed subject matter has been described and illustrated in the foregoing illustrative embodiments, it is understood that the present disclosure has been made only by way of example, and that numerous changes in the details of embodiment of the disclosed subject matter can be made without departing from the spirit and scope of the disclosed subject matter, which is only limited by the claims which follow. Features of the disclosed embodiments can be combined and rearranged in various ways. Without departing from the spirit and scope of the disclosed subject matter modifications, equivalents, or improvements to the disclosed subject matter are understandable to those skilled in the art and are intended to be encompassed within the scope of the present disclosure.

1-22. (canceled)

23. A method for forming a thin film transistor, comprising:
forming a pattern of an active layer on a base substrate and insulated from a gate electrode;
forming a pattern of a first initial ohmic contacting layer and a second initial ohmic contacting layer on the active layer;
forming a pattern of a source electrode on the first initial ohmic contacting layer, and a pattern of a drain electrode on the second initial ohmic contacting layer; and
performing a heating treatment to the base substrate having the source electrode and the drain electrode thereon, such that metal atoms in the source electrode diffuse to the first initial ohmic contacting layer to form a first ohmic contacting layer, and metal atoms in the drain electrode diffuse to the second initial ohmic contacting layer to form a second ohmic contacting layer.

24. The method of claim 23, wherein:
the first initial ohmic contacting layer and the second initial ohmic contacting layer are located in a same layer and are oppositely positioned; and
a material of the first initial ohmic contacting layer and the second initial ohmic contacting layer is metal oxide or metal oxynitride.

25. The method of claim 23, further comprising:
after forming the pattern of the first initial ohmic contacting layer and the second initial ohmic contacting layer, forming a pattern of the gate electrode;
wherein the gate electrode is insulated from the first initial ohmic contacting layer and the second initial ohmic contacting layer.

26. The method of claim 25, wherein the pattern of the gate electrode is formed before forming the pattern of the source electrode and the drain electrode.

27. The method of claim 26, further comprising:
after forming the pattern of the first initial ohmic contacting layer and the second initial ohmic contacting layer and before forming the pattern of the gate electrode, forming a gate insulating layer on the first initial ohmic contacting layer and the second initial ohmic contacting layer.

28. The method of claim 27, further comprising:
after forming the pattern of the gate electrode and before forming the pattern of the source electrode and the drain electrode, forming an interlayer dielectric layer covering the gate electrode; and
forming a first via-hole and a second via-hole passing through the gate insulating layer and the interlayer dielectric layer, wherein the first via-hole is used for electrically connecting the first initial ohmic contacting layer with a to-be-formed source electrode, and the second via-hole is used for electrically connecting the second initial ohmic contacting layer with a to-be-formed drain electrode.

29. The method of claim 24, wherein the material of the first initial ohmic contacting layer and the second initial ohmic contacting layer includes at least one element of Indium (In), zinc (Zn), gallium (Ga), and tin (Sn).

30. A thin film transistor, comprising:
a gate electrode;
an active layer insulated from the gate electrode;
a source electrode and a drain electrode on the active layer;
a first ohmic contacting layer located between the source electrode and the active layer, wherein a material of the first ohmic contacting layer is formed by diffusing metal atoms in the source electrode to a metal oxide or a metal oxynitride; and
a second ohmic contacting layer located between the drain electrode and the active layer, wherein a material of the second ohmic contacting layer is formed by diffusing metal atoms in the drain electrode to a metal oxide or a metal oxynitride;
wherein the source electrode is electrically connected with the active layer through the first ohmic contacting layer, and the drain electrode is electrically connected with the active layer through the second ohmic contacting layer.

31. The thin film transistor of claim 30, wherein a material of the active layer is polysilicon.

32. The thin film transistor of claim 30, wherein the gate electrode is located above the first ohmic contacting layer and the second ohmic contacting layer.

33. The thin film transistor of claim 30, wherein the source electrode and the drain electrode are located above the gate electrode.

34. The thin film transistor of claim 30, further comprising a gate insulating layer between the gate electrode and the first ohmic contacting layer, and between the gate electrode and the second ohmic contacting layer.

35. The thin film transistor of claim 34, further comprising:
an interlayer dielectric layer between the gate electrode and the source electrode as well as the drain electrode; and
a first via-hole and a second via-hole passing through the gate insulating layer and the interlayer dielectric layer;
wherein the first initial ohmic contacting layer is electrically connected to source electrode through the first via-hole, and the second initial ohmic contacting layer is electrically connected with the drain electrode through the second via-hole.

36. The thin film transistor of claim 30, wherein the material of the first initial ohmic contacting layer and the material of the second initial ohmic contacting layer include at least one element of Indium (In), zinc (Zn), gallium (Ga), and tin (Sn).

37. The thin film transistor of claim 30, wherein the metal atoms are copper atoms.

38. An array substrate, comprising the thin film transistor according to claims 8.

39. The array substrate of claim 38, further comprising:
a planarization layer and a pixel electrode that are located above the thin film transistor;
wherein the pixel electrode is electrically connected with the drain electrode of the thin film transistor.

40. The array substrate of claim 39, wherein:
the array substrate is used in an liquid crystal display panel; and
the pixel electrode is a pixel electrode of the liquid crystal display panel.

41. The array substrate of claim 40, wherein:
the array substrate is used in an organic electroluminescent display panel; and
the pixel electrode is an anode layer or a cathode layer of an organic light emitting structure of the organic electroluminescent display panel.

42. A display apparatus, comprising the array substrate according to claim 38.
